(19) United States
(12) Patent Application Publication
(10) Pub. No.: US 2016/0093672 A1
(43) Pub. Date: Mar. 31, 2016

(54) LOGIC HIGH-K/METAL GATE 1T-1C RRAM MTP/OTP DEVICES

(71) Applicant: QUALCOMM Incorporated, San Diego, CA (US)

(72) Inventors: Xia LI, San Diego, CA (US); Daniel Wayne PERRY, JR., San Diego, CA (US); Seung Hyuk KANG, San Diego, CA (US)

(21) Appl. No.: 14/499,004

(22) Filed: Sep. 26, 2014

(51) Int. Cl. H01L 27/24; G11C 13/00; H01L 45/00

(52) U.S. Cl. CPC H01L 27/2418; H01L 45/1233; H01L 45/1253; H01L 45/16; G11C 13/0069

(57) ABSTRACT

Methods and apparatuses, wherein the method includes providing a logic device. The method substantially surrounds a metal gate with a transition metal oxide on at least one side, wherein the transition metal oxide is comprised of hafnium oxalate and silicon dioxide. The method provides a bottom electrode (BE), wherein the BE is comprised of at least one of silicon or tungsten.

### BACKGROUND OF THE INVENTION

1. Field of the Invention

Disclosed implementations relate to logic gated diodes and toward a method of forming same.

2. Description of the Related Art

Non-volatile memories are widely adopted in electronic products such as cell phones, digital cameras, and digital music players. These non-volatile memories are usually hard drives, flash memories, and OTP memories. Flash memories and OTP memories are two common types of memories. The major difference between these two kinds of memories is that a flash memory is refreshable while an OTP memory can only be written once. More specifically, a flash memory is capable of being read and written many times, but once an OTP memory is programmed, i.e., when some data are written into an OTP memory, the OTP memory cannot be overwritten.

A flash memory is a multi-time programmable (MTP) memory which is capable of being repeatedly written and erased, and therefore a flash memory requires some circuits that perform the erase, write, and read operations. However, an OTP memory requires only write and read operations but no erase operation; therefore, compared to an MTP memory, an OTP memory does not require a circuit to perform the erase operation. The simplicity of an OTP memory leads to a simpler and low-cost manufacturing process of the circuit of the OTP memory. Under a circumstance where only a few read and write processes are required, a plurality of OTP memories is often utilized to simulate an MTP memory. As a result, the performance of a MTP memory can be achieved without an additional erase circuit.

FIG. 1A illustrates known materials for HfO₂-based RRAM. The top electrode 102 can include titanium nitride. The next layer 104 can include hafnium oxide. The third layer 106 can include silicon oxide. The bottom electrode 108 can include silicon.

FIG. 1B illustrates known materials for HfO₂-based RRAM. The top electrode 152 can include titanium nitride. The next layer 154 can include titanium. The third layer 156 can include hafnium oxide. The bottom electrode 158 can include titanium nitride.

FIG. 2A illustrates a known RRAM device 200. The known device 200 can include a voltage source 202, a resistor 204, and a switcher 206. The resistor 204 can include a top electrode 212 made of metal, an insulator 214, and a bottom electrode 216 metal. The switcher 206 can include a switcher 218. The known RAM device 200 can include a back end of the line, which can add three metallization layers. The known RAM device 200 may not have a hard breakdown OTP.

FIG. 2B illustrates a known antifuse OTP device in two different states. When the known OTP device is in a first state 250, which can be prior to programming, a bit line signal 252 can receive information from a WLP signal through a first MOSCap 254, wherein the first MOSCap 254 is in series with a second transistor 256 that is receiving a WLR signal.

When the known device is in a second state 270, which can be after programming, a bit line 272 receives information from a resistor 274 and a transistor 276. The MOSCap 254 can breakdown to become the resistor 274. A WLR signal is still received by the transistor 276, but a WLP signal passes through the resistor 274.

### SUMMARY

The disclosure is directed to logic gated diodes and toward a method of forming same.

An apparatus can comprise a metal gate, wherein a transition metal oxide substantially surrounds the metal gate on at least one side. The apparatus can comprise the transition metal oxide, wherein the transition metal oxide is comprised of hafnium oxalate and silicon dioxide. The apparatus can comprise a bottom electrode (BE), wherein the BE is comprised of at least one of silicon or tungsten.

A method can comprise substantially surrounding a metal gate with a transition metal oxide on at least one side, wherein the transition metal oxide is comprised of hafnium oxalate and silicon dioxide. The method can comprise providing a BE, wherein the BE is comprised of at least one of silicon or tungsten.

An embedded non-volatile memory device can comprise a metal gate, wherein a transition metal oxide substantially surrounds the metal gate on at least one side. The embedded non-volatile memory device can comprise the transition metal oxide, wherein the transition metal oxide is comprised of hafnium oxalate and silicon dioxide. The embedded non-volatile memory device can comprise a BE, wherein the BE is comprised of at least one of silicon or tungsten.

This can allow for multiple program function and final one time program function. It can also scale with high-K dielectric metal gate (HK/MG) technology.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1A illustrates known materials for HfO₂-based RRAM.

FIG. 1B illustrates known materials for HfO₂-based RRAM.

FIG. 2A illustrates a known RRAM device.

FIG. 2B illustrates a known OTP device.

FIG. 3A is an exemplary graphical representation of logic HK/MG HfO₂ gate-to-contact device switching to a set state.

FIG. 3B is an exemplary graphical representation of a logic HK/MG HfO₂ gate-to-contact device during a read state after a set state.

FIG. 4A is an exemplary graphical representation of a logic HK/MG HfO₂ gate-to-contact device switching to a reset state.

FIG. 4B is an exemplary graphical representation of a logic HK/MG HfO₂ gate-to-contact device during a read state after switching to a reset state.

FIG. 5 is an exemplary graphical representation of a logic HK/MG HfO₂ gate-to-contact device setting/resetting multiple times.

FIG. 6 is an exemplary graphical representation of a logic HK/MG HfO₂ FinFET device set/reset switch.

FIG. 7 is an exemplary graphical representation of a dielectric soft breakdown of a logic HK/MG HfO₂ FinFET device.

FIG. 8 is an exemplary graphical representation of a dielectric soft rupture and breakdown of a logic HK/MG HfO₂ FinFET device.

FIG. 9 is an exemplary graphical representation of a dielectric soft breakdown for set switching.

FIG. 10 is an exemplary graphical representation of a dielectric soft rupture and breakdown for reset and set switching.

FIG. 11A illustrates an exemplary 1T-1R N gated diode RRAM MTP/OTP device.

FIG. 11B illustrates an exemplary 1T-1R P gated diode RRAM MTP/OTP device.

FIG. 11C illustrates an exemplary 1T-1T N MOS RRAM MTP/OTP device.

FIG. 11D illustrates an exemplary 1T-1T P MOS RRAM MTP/OTP device.

FIG. 11E illustrates an exemplary 1T-1T N MOS RRAM MTP/OTP device.

FIG. 11F illustrates an exemplary 1T-1T P MOS RRAM MTP/OTP device.

FIG. 11G illustrates an exemplary 1T-1C N gate to a CT MiM-Cap RRAM MTP/OTP device.

FIG. 11H illustrates an exemplary 1T-1C P gate to a CT MiM-Cap RRAM MTP/OTP device.

FIG. 11I illustrates an exemplary 1T-1C N gate to a MiM-Cap Fe/RRAM MTP/OTP device.

FIG. 11J illustrates an exemplary 1T-1C P gate to a MiM-Cap Fe/RRAM MTP/OTP device.

FIG. 12A illustrates exemplary materials for a logic FinFET HK/MG RRAM device.

FIG. 12B illustrates exemplary materials for a logic FinFET HK/MG RRAM device.

FIG. 13 illustrates an exemplary logic FinFET HK/MG RRAM MTP device.

FIG. 14 illustrates an exemplary logic FinFET HK/MG RRAM MTP device.

FIG. 15 illustrates an exemplary logic FinFET HK/MG RRAM MTP device.

FIG. 16 illustrates an exemplary logic FinFET HK/MG RRAM MTP device.

FIG. 17A illustrates exemplary materials for a logic planar HK/MG RRAM device.

FIG. 17B illustrates exemplary materials for a logic planar HK/MG RRAM device.

FIG. 18 illustrates an exemplary logic planar HK/MG RRAM MTP device.

FIG. 19 illustrates an exemplary logic planar HK/MG RRAM MTP device.

FIG. 20 illustrates an exemplary logic planar HK/MG RRAM MTP device.

FIG. 21 illustrates an exemplary logic planar HK/MG RRAM MTP device.

FIG. 22 illustrates an operational flow of a method.

FIG. 23 is a block diagram showing an exemplary wireless communication system in which an embodiment of the disclosure may be advantageously employed.

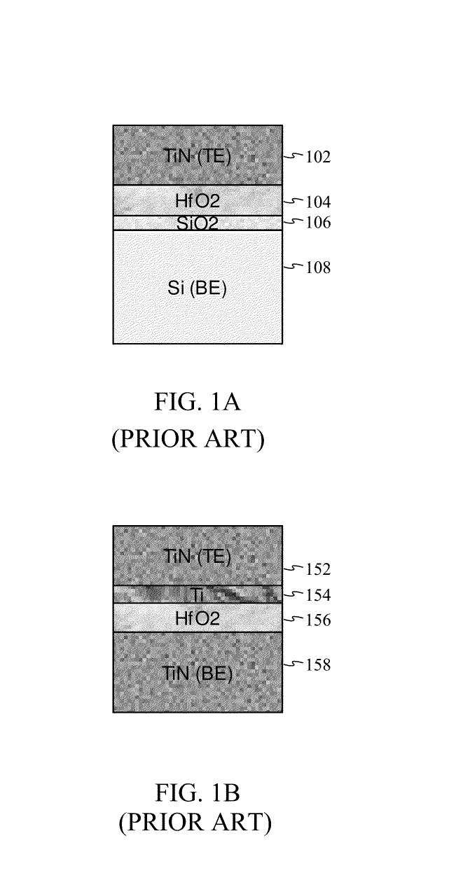

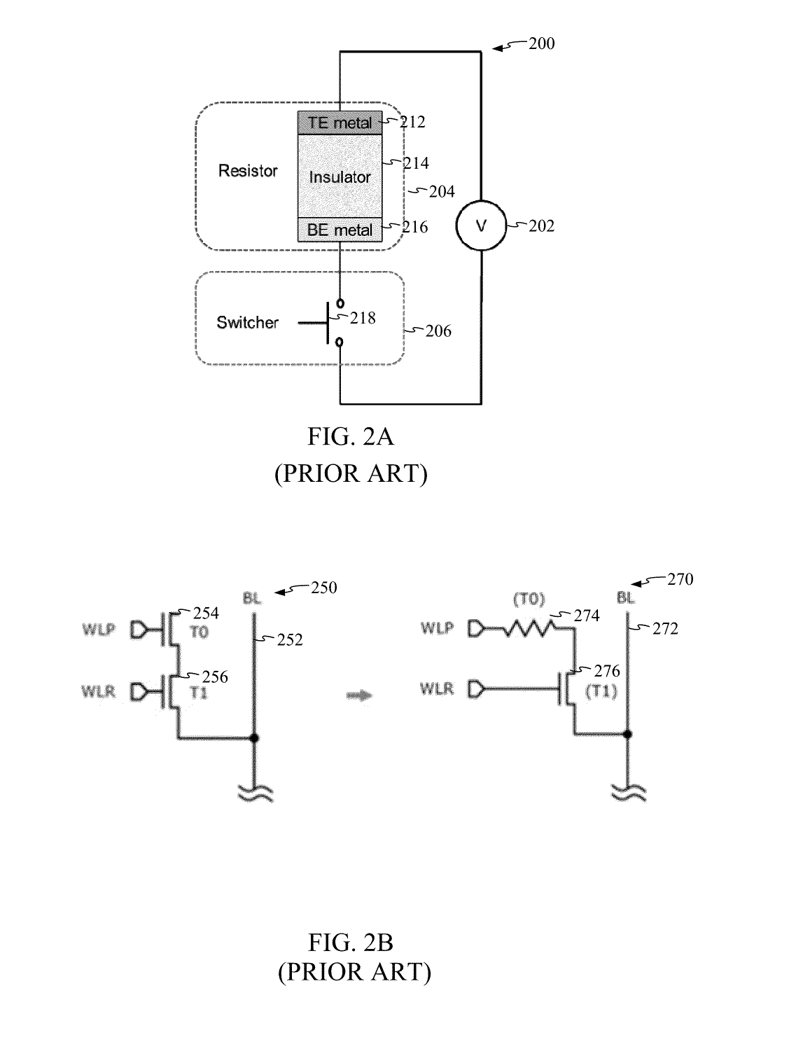

### DETAILED DESCRIPTION

Various aspects are disclosed in the following description and related drawings. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

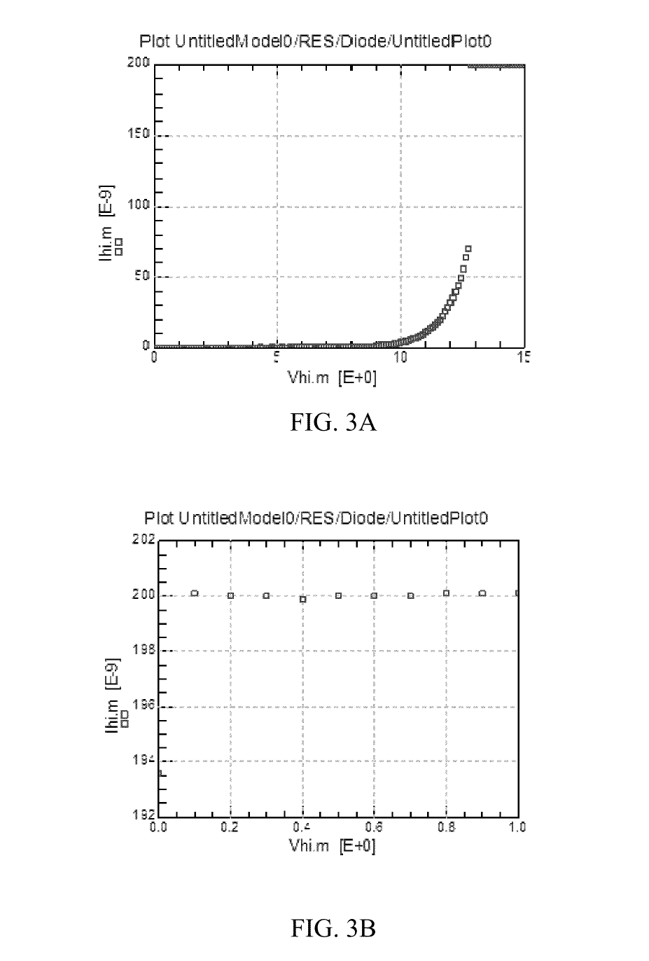

FIG. 3A is an exemplary graphical representation of a logic HK/MG HfO₂ gate-to-contact device switching to a set state. As shown, the amperage increases to less than approximately 200 nA and compliance at 200 nA as the voltage increases to maintain soft breakdown.

FIG. 3B is an exemplary graphical representation of a logic HK/MG HfO₂ gate-to-contact device during a read state after a set state. As shown, the amperage remains at approximately 200 nA.

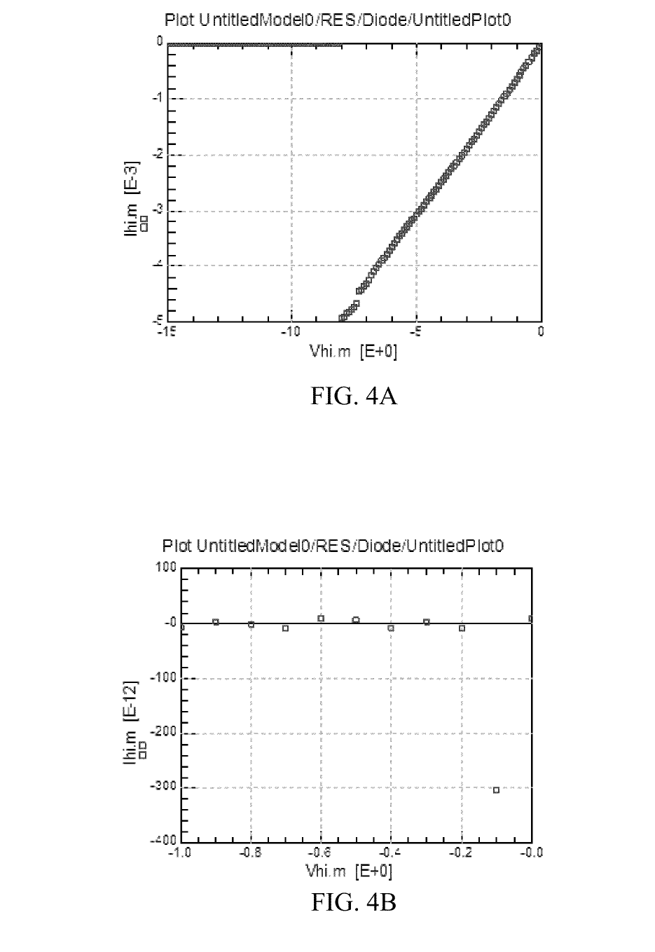

FIG. 4A is an exemplary graphical representation of a logic HK/MG HfO₂ gate-to-contact device switching to a reset state. As shown, the reset triggers less than 5 mA through its cycle.

FIG. 4B is an exemplary graphical representation of a logic HK/MG HfO₂ gate-to-contact device during a read state after switching to a reset state. As shown, the amperage remains at approximately 10 pA, close to zero.

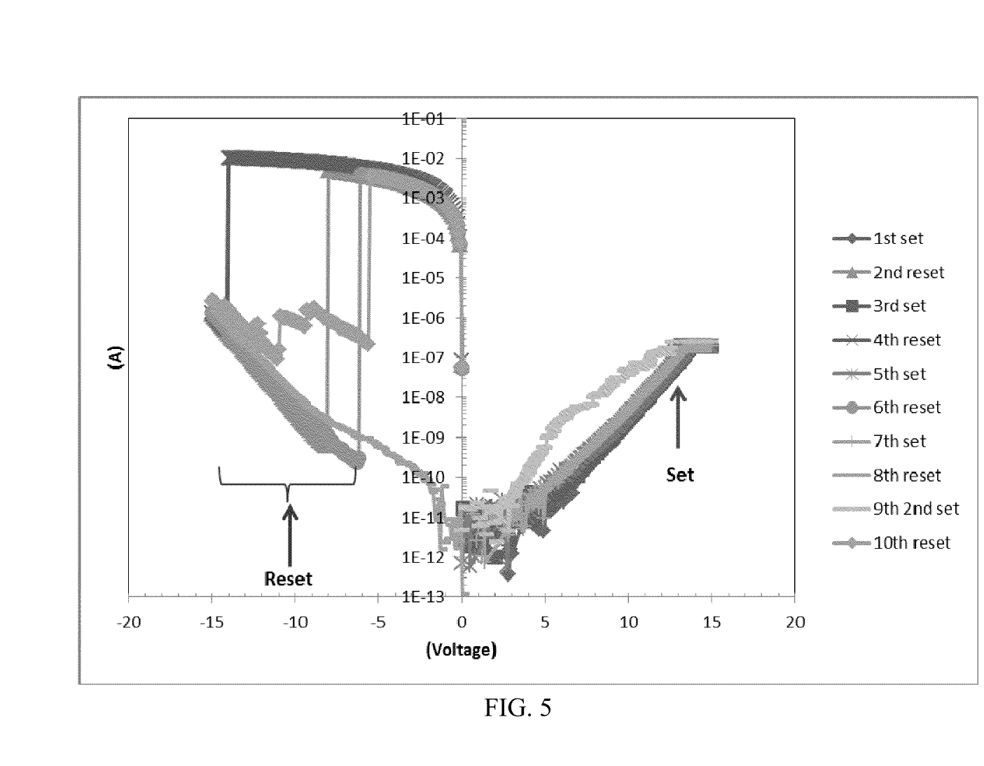

FIG. 5 is an exemplary graphical representation of a logic HK/MG HfO₂ gate-to-contact device setting/resetting multiple times. As shown, the set cycles provide a similar path each time. The reset cycles, however, show some variation at the beginning of the cycle, but tend to follow the same path overall.

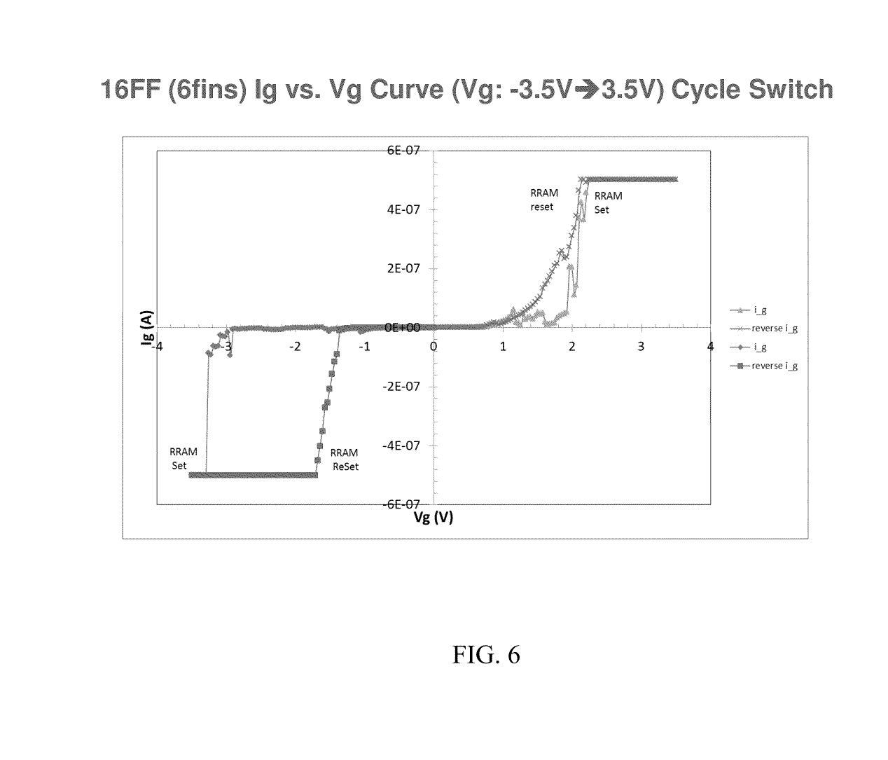

FIG. 6 is an exemplary graphical representation of a logic HK/MG HfO₂ FinFET device set/reset switch.

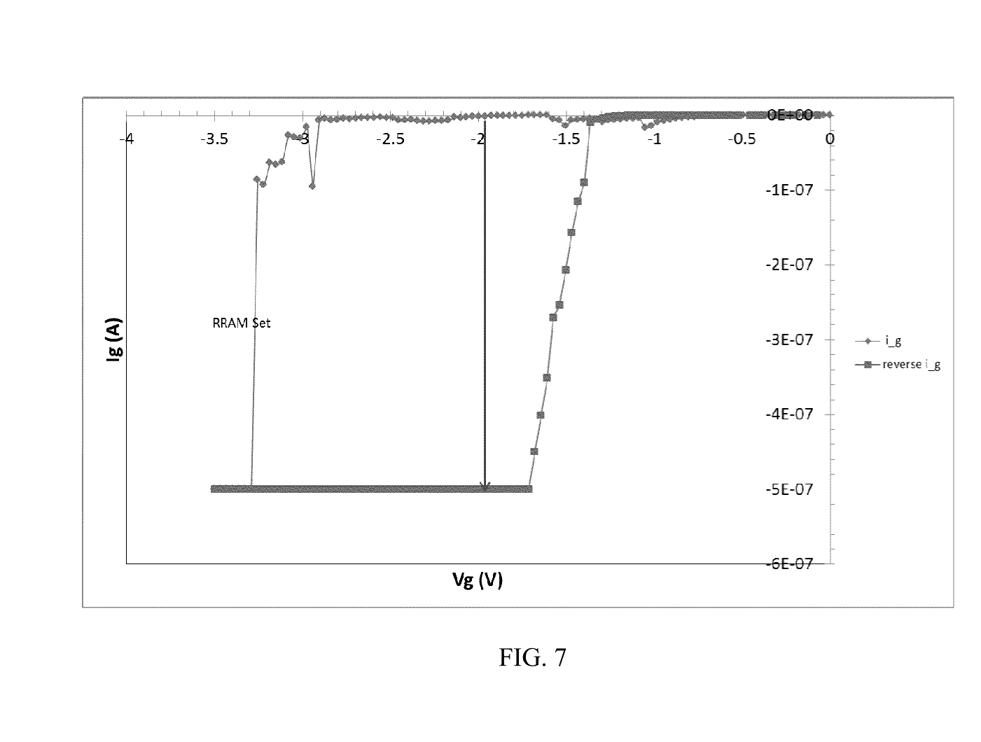

FIG. 7 is an exemplary graphical representation of a dielectric soft breakdown of a logic HK/MG HfO₂ FinFET device. After a dipole is switched such that it is greater than the v_{sw}, a gate current can be increased for an RRAM set.

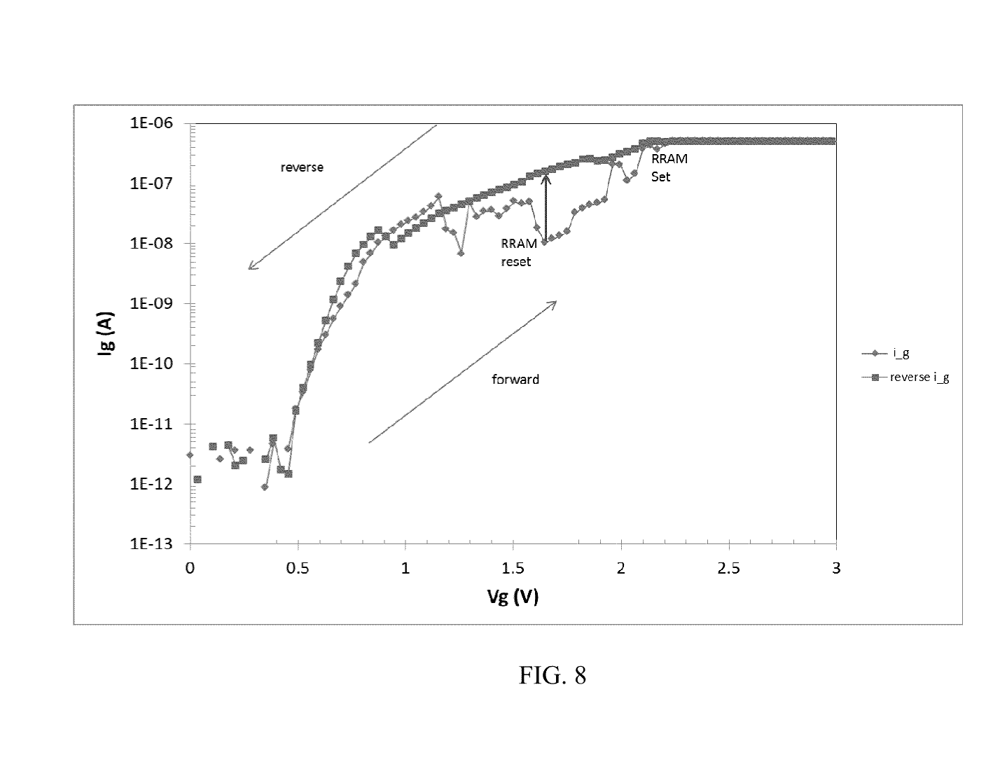

FIG. 8 is an exemplary graphical representation of a dielectric soft rupture and breakdown of a logic HK/MG HfO₂ FinFET device. After a dipole is switched such that it is greater than the v_{sw}, a gate current can be decreased and increased for an RRAM set/reset.

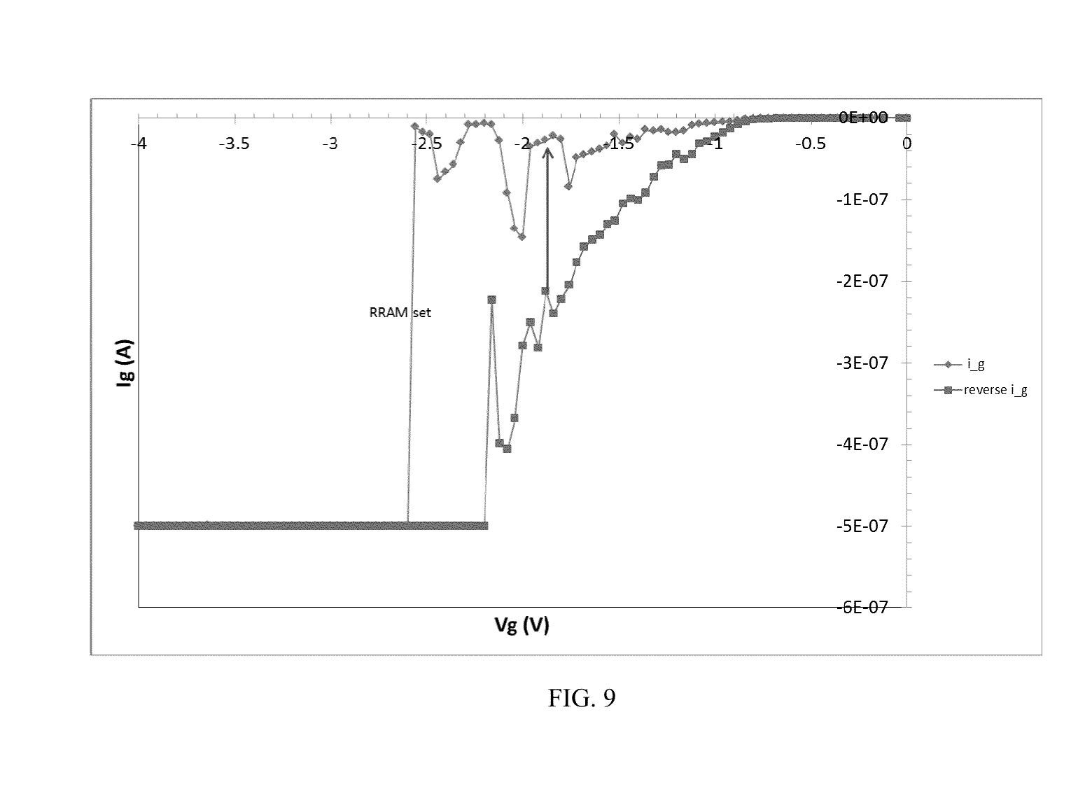

FIG. 9 is an exemplary graphical representation of a dielectric soft breakdown a logic HK/MG HfO₂ FinFET device. After a dipole is switched such that it is greater than the v_{sw}, a gate current can be increased for an RRAM set.

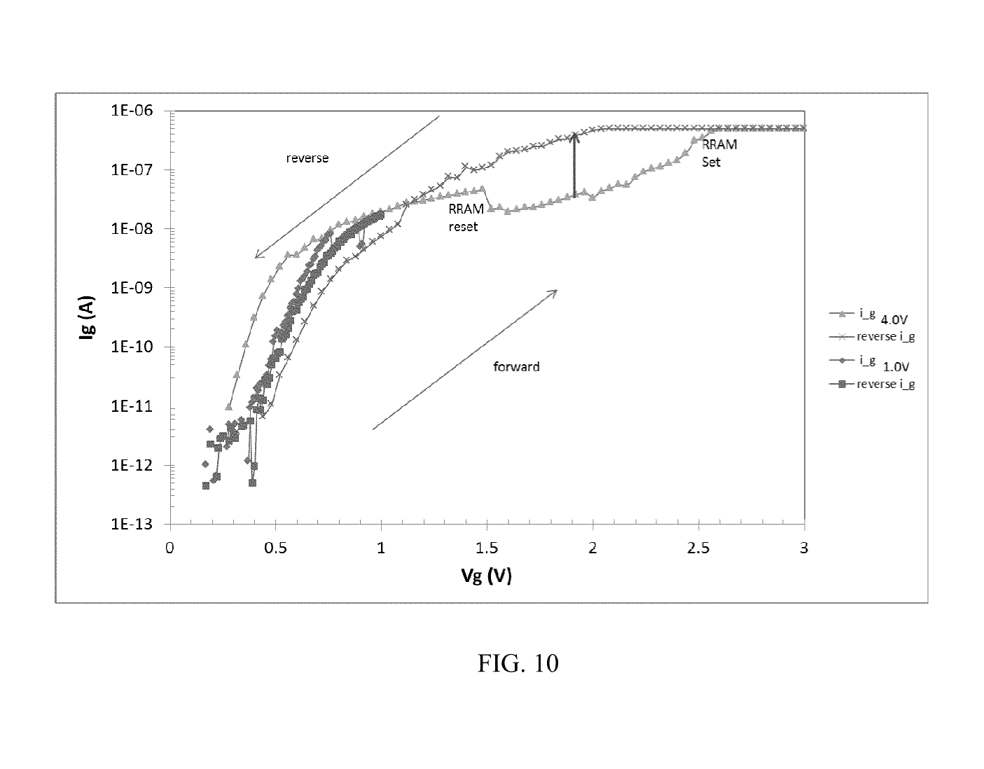

FIG. 10 is an exemplary graphical representation of a dielectric soft rupture and breakdown. After a dipole is switched such that it is greater than the v_{sw}, a gate current can be decreased for an RRAM reset and increased for an RRAM set.

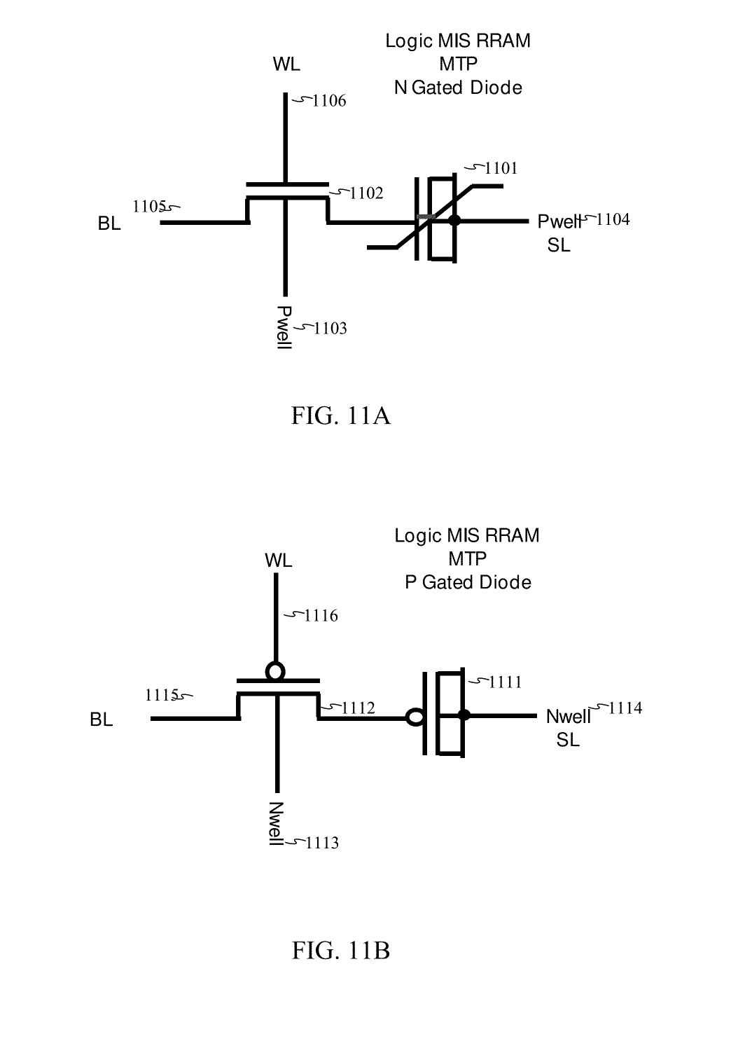

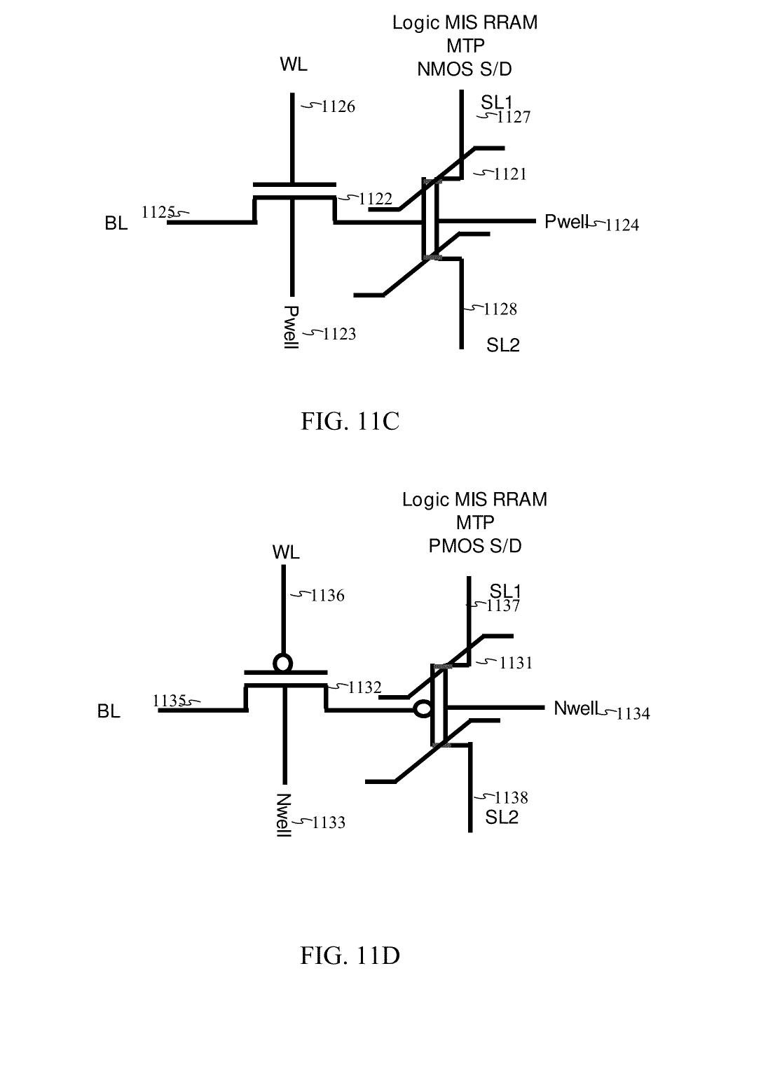

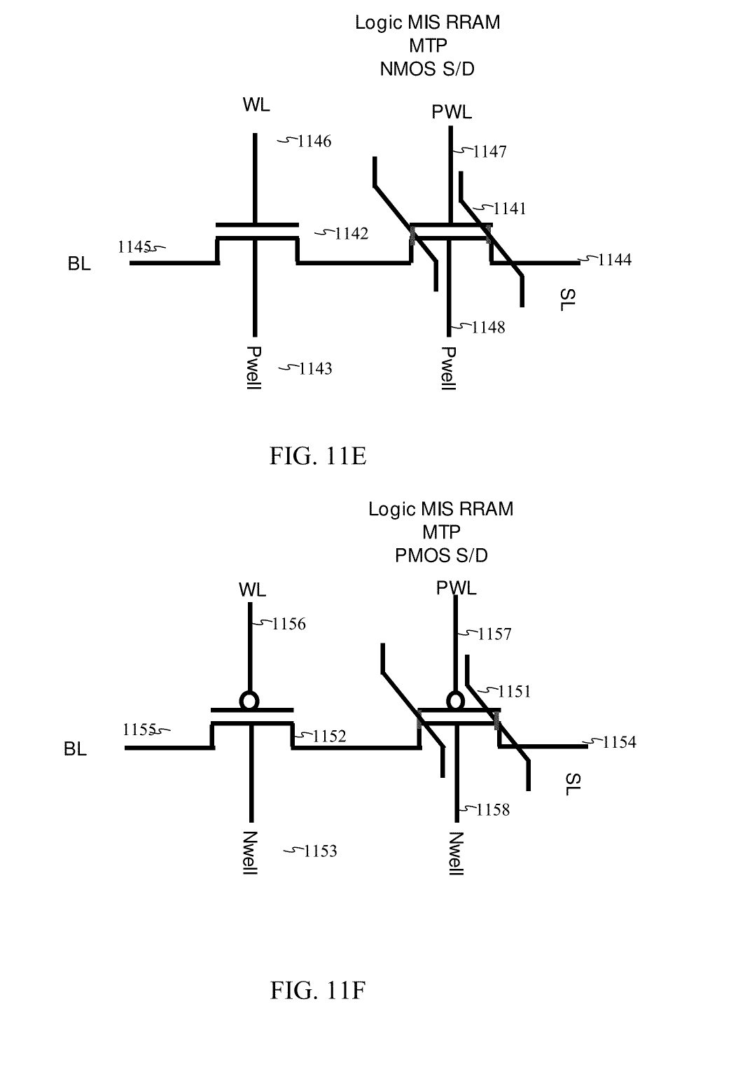

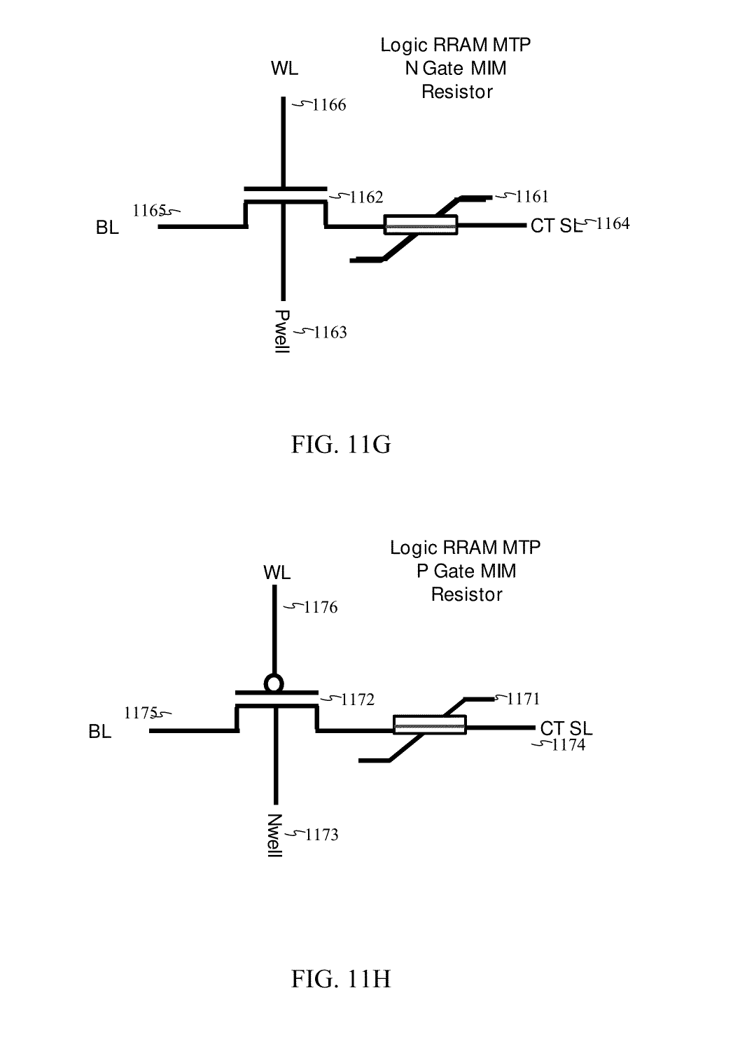

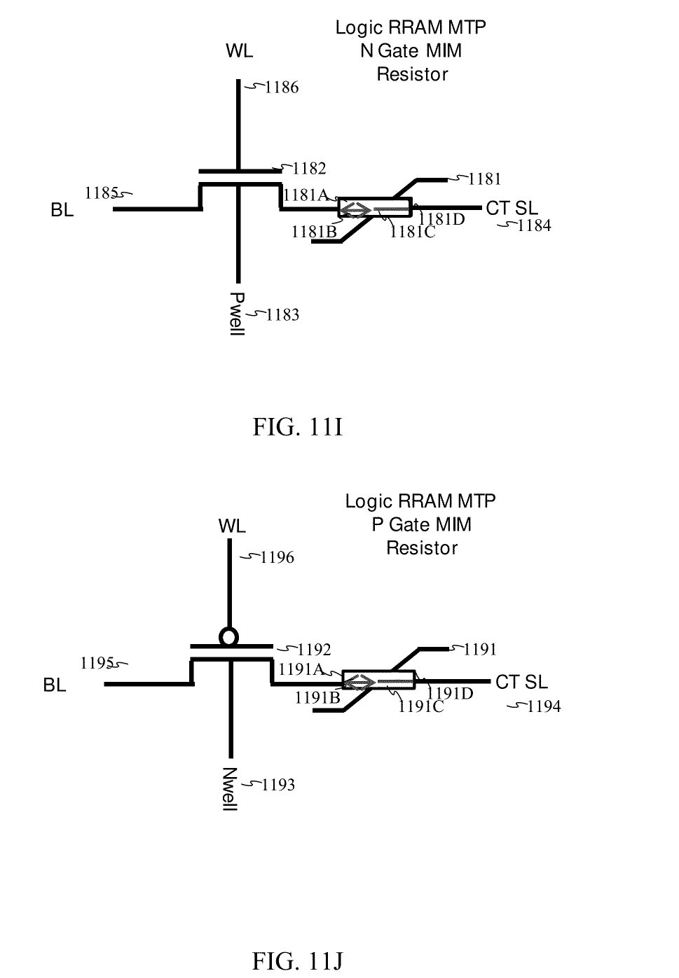

FIG. 11A illustrates an exemplary 1T-1R N gated diode RRAM MTP/OTP device 1100. The device 1100 includes a logic MIS RRAM MTP N gated diode 1101 and an access transistor 1102. The access transistor is coupled to a P-well 1103, a P-well SL line 1104, a bit line 1105, and a word line 1106.

In some embodiments, the logic gated diode 1101 is associated with a HfOx/SiO2 barrier soft breakdown (RLS) and rupture (RHS). In some embodiments, the logic gated diode 1101 is associated with an HfOx/SiO2 barrier hard breakdown (Rbrk) (low resistance anti-fuse). In some embodiments, the device 1100 can include an access transistor and gated diode RRAM MTP cell. For example, the access transistor can be an 110 device.

FIG. 11B illustrates an exemplary 1T-1R P gated diode RRAM MTP/OTP device. The device 1110 includes a logic MIS RRAM MTP P gated diode 1111 and an access transistor 1112. The access transistor is coupled to an N-well 1113, an N-well SL line 1114, a bit line 1115, and a word line 1116.

In some embodiments, the logic device 1110 can have similar characteristics as the logic device 1100.

FIG. 11C illustrates an exemplary 1T-1T N MOS RRAM MTP/OTP device 1120. The device 1120 includes a logic MIS RRAM MTP NMOS 1121 and an access transistor 1122. The access transistor is coupled to a first P-well 1123, a second P-well 1124, a bit line 1125, a word line 1126, a first source line 1127, and a second source line 1128.

In some embodiments, the logic device 1120 can be sequential and/or dynamic (S/D) MOS RRAM MTP. In some embodiments, the logic device 1120 can be associated with HfOx/SiO2 barrier RLS and RHS. In some embodiments, the logic device 1120 can be associated with an HfOx/SiO2 barrier Rbrk. In some embodiments, the device 1200 can include an access transistor and a MOS S/D RRAM logic MTP cell. For example, the access transistor can be an I/O device.

FIG. 11D illustrates an exemplary 1T-1T P MOS RRAM MTP/OTP device 1130. The device 1130 includes a logic MIS RRAM MTP PMOS 1131 and an access transistor 1132. The access transistor is coupled to a first N-well 1133, a second N-well 1134, a bit line 1135, a word line 1136, a first source line 1137, and a second source line 1138.

In some embodiments, the logic device 1130 can have similar characteristics as the logic device 1120.

FIG. 11E illustrates an exemplary 1T-1T N MOS RRAM MTP/OTP device 1140. The device 1140 includes a logic MIS RRAM MTP NMOS 1141 and an access transistor 1142. The access transistor is coupled to a first P-well 1143, a source line 1144, a bit line 1145, a word line 1146, a program-word line 1147, and a second P-well 1148.

In some embodiments, the logic device 1140 can have similar characteristics as the logic device 1120.

FIG. 11F illustrates an exemplary 1T-1T P MOS RRAM MTP/OTP device 1150. The device 1150 includes a logic MIS RRAM MTP PMOS 1151 and an access transistor 1152. The access transistor is coupled to a first N-well 1153, a source line 1154, a bit line 1155, a word line 1156, a program-word line 1157, and a second N-well 1158.

In some embodiments, the logic device 1150 can have similar characteristics as the logic device 1120.

FIG. 11G illustrates an exemplary 1T-1C N gate to a CT MiM-Cap RRAM MTP/OTP device 1160. The device 1160 includes a logic RRAM MTP N gate MiM capacitor 1161 and an access transistor 1162. The access transistor is coupled to a P-well 1163, a contact to source line 1164, a bit line 1165, and a word line 1166.

In some embodiments, the logic device 1160 can be associated with an HfOx/SiN/SiO2 bather RLS and RHS. In some embodiments, the logic device 1160 can be associated with a HfOx/SiN/SiO2 barrier Rbrk. In some embodiments, the logic device 1160 can include an access transistor and MiM RRAM MTP cell. For example, the access transistor can be an I/O device or a high voltage device.

FIG. 11H illustrates an exemplary 1T-1C P gate to a CT MiM-Cap RRAM MTP/OTP device 1170. The device 1170 includes a logic RRAM MTP P gate MiM capacitor 1171 and an access transistor 1172. The access transistor is coupled to an N-well 1173, a contact to source line 1174, a bit line 1175, and a word line 1176.

In some embodiments, the logic device 1170 can have similar characteristics as the logic device 1160.

FIG. 11I illustrates an exemplary 1T-1C MiM-Cap Fe/RRAM MTP/OTP device 1180. The device 1180 includes a Fe/RRAM MTP MiM capacitor 1181 and an access transistor 1182. The access transistor is coupled to a P-well 1183, a contact to source line 1184, a bit line 1185, and a word line 1186. The MiM capacitor 1181 includes a top electrode 1181A, a dipole 1181B, an RRAM conductive filament 1181C, and a bottom electrode 1181D.

The logic device 1180 can be associated with a ferroelectric dipole up or down/RRAM barrier RLS and ferroelectric dipole down or up/RRAM RHS. The logic device 1180 can be associated with a ferroelectric dipole up or down/RRAM Rbrk. In some embodiments, the device 1100 can include an access transistor and a MiM-Cap ferroelectric dipole/RRAM RRAM MTP/OTP cell. For example, the access transistor can be an I/O device or a high voltage device. The logic device 1180 may require Vfe_sw>Vset or Vreset.

FIG. 11J illustrates an exemplary 1T-1C MiM-Cap Fe/RRAM MTP/OTP device 1190. The device 1190 includes an Fe/RRAM MTP MiM capacitor 1191 and an access transistor 1192. The access transistor is coupled to an N-well 1193, a contact to source line 1194, a bit line 1195, and a word line 1196. The logic capacitor 1191 includes a top electrode 1191A, a dipole 1191B, an RRAM conductive filament 1191C, and a bottom electrode 1191D.

In some embodiments, the logic device 1190 can have similar characteristics as the logic device 1180.

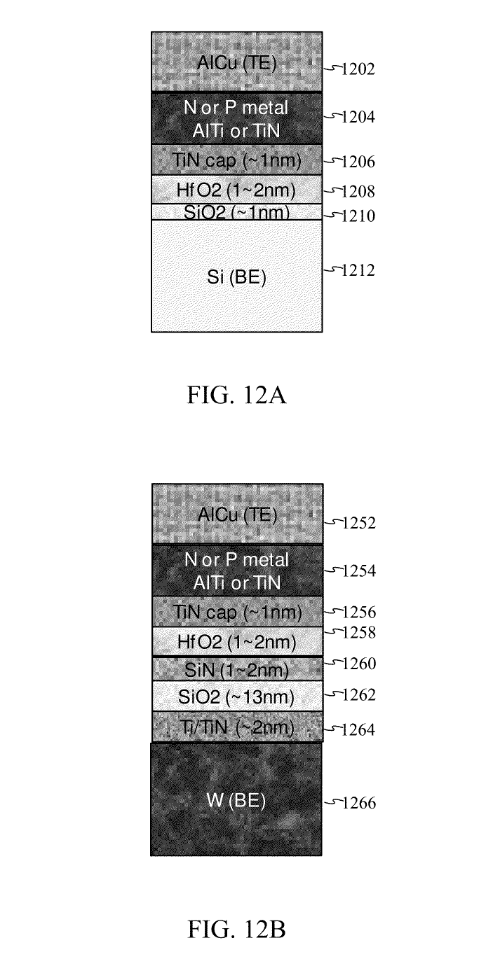

FIG. 12A illustrates exemplary materials for a logic FinFET HK/MG RRAM device. A top end 1202 can include aluminum copper. An N or P metal 1204 can include aluminum titanium or titanium nitride. A layer 1206 can include titanium nitride. The layer 1206 can be approximately one nanometer in thickness. The device can include a hafnium oxide layer 1208 that can be approximately one to two nanometers in thickness. The device can also include a silicon oxide layer 1210 than can be approximately one nanometer in thickness. A bottom electrode 1212 can include silicon.

FIG. 12B illustrates exemplary materials for a logic FinFET HK/MG RRAM device. A top end 1252 can include aluminum copper. An N or P metal 1254 can include aluminum titanium or titanium nitride. A layer 1256 can include titanium nitride. The layer 1256 can be approximately one nanometer in thickness. The device can include a hafnium oxide layer 1258 that can be approximately one to two nanometers in thickness. The device can also include a silicon nitride layer 1260 than can be approximately one to two nanometers in thickness. The device can also include a silicon oxide layer 1262 than can be approximately thirteen nanometers in thickness. The device can include a titanium and/or titanium nitride layer 1264 than can be approximately two nanometers in thickness. A bottom electrode 1266 can include tungsten.

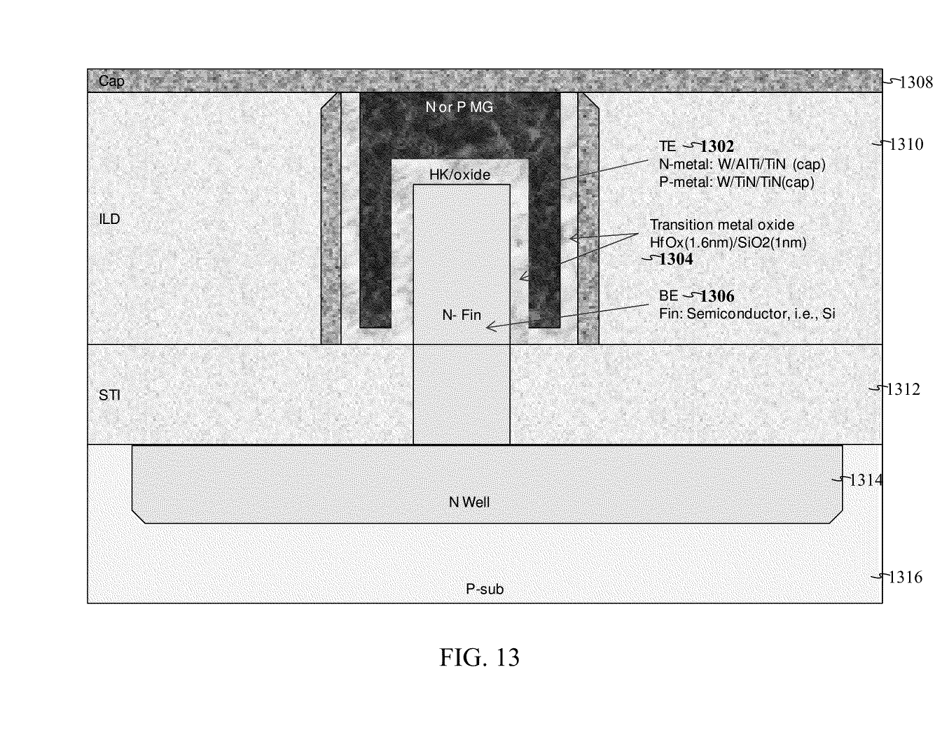

FIG. 13 illustrates an exemplary logic FinFET HK/MG RRAM MTP device 1300. The logic device 1300 can include a top electrode (TE) (metal gate) 1302 substantially surrounded on at least three sides by a transition metal oxide 1304. A bottom electrode (BE) 1306 can be substantially surrounded on at least three sides by the TE (metal gate) 1302 and the transition metal oxide 1304. A cap layer 1308 can substantially surround the metal gate 1302. The cap layer 1308 can cover an interlevel dielectric layer (ILD) 1310. The logic device can also include a shallow trench isolation (STI) 1312, an N-well 1314, and a P-sub 1316.

In some embodiments, the TE 1302 can include an N-metal or a P-metal. The N-metal can be various metals, such as tungsten, aluminum titanium, and titanium nitride. The P-metal can be various metals, such as tungsten and titanium nitride.

In some embodiments, the transition metal oxide 1304 can be various metals. For example, the transition metal oxide 1304 can include hafnium oxide and silicon oxide. In one example, the hafnium oxide can be 1.6 nanometers thick. In one example, the silicon oxide can be one nanometer thick.

In some embodiments, the BE 1306 can include an N-Fin. The BE can include a semiconductor, such as silicon. In some embodiments, the cap layer 1308 can be comprised of silicon nitride.

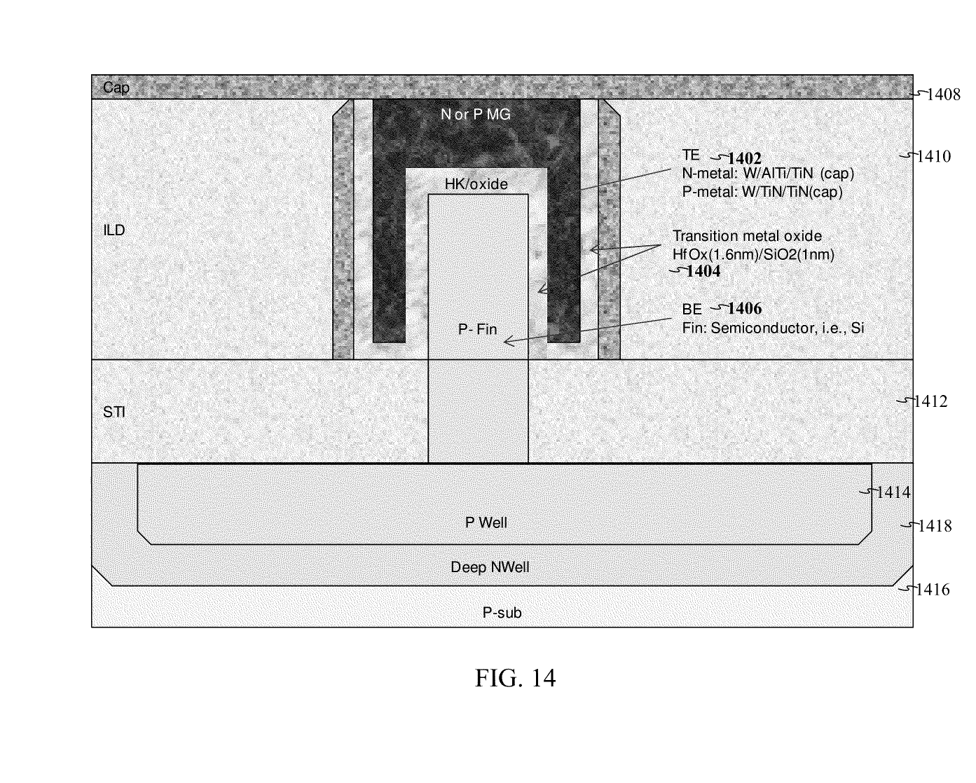

FIG. 14 illustrates an exemplary logic FinFET HK/MG RRAM MTP device 1400. The logic device 1400 can include a TE (metal gate) 1402 substantially surrounded on at least three sides by a transition metal oxide 1404. A BE (Fin) 1406 can be substantially surrounded on at least three sides by the TE (metal gate) 1402 and the transition metal oxide 1404. A cap layer 1408 can substantially surround the transition metal oxide 1408. The cap layer 1408 can cover an ILD 1410. The logic device can also include an STI 1412, an P-well 1414, a P-sub 1416, and a deep N-well 1418.

In some embodiments, the TE (metal gate) 1402 can include an N-metal or a P-metal. The N-metal can be various metals, such as tungsten, aluminum titanium, and titanium nitride. The P-metal can be various metals, such as tungsten and titanium nitride.

In some embodiments, the transition metal oxide 1404 can be various metals. For example, the transition metal oxide 1404 can include hafnium oxide and silicon oxide. In one example, the hafnium oxide can be 1.6 nanometers thick. In one example, the silicon oxide can be one nanometer thick.

In some embodiments, the BE (Fin) 1406 can include a P-Fin. The BE can include a semiconductor, such as silicon. In some embodiments, the cap layer 1408 can be comprised of silicon nitride.

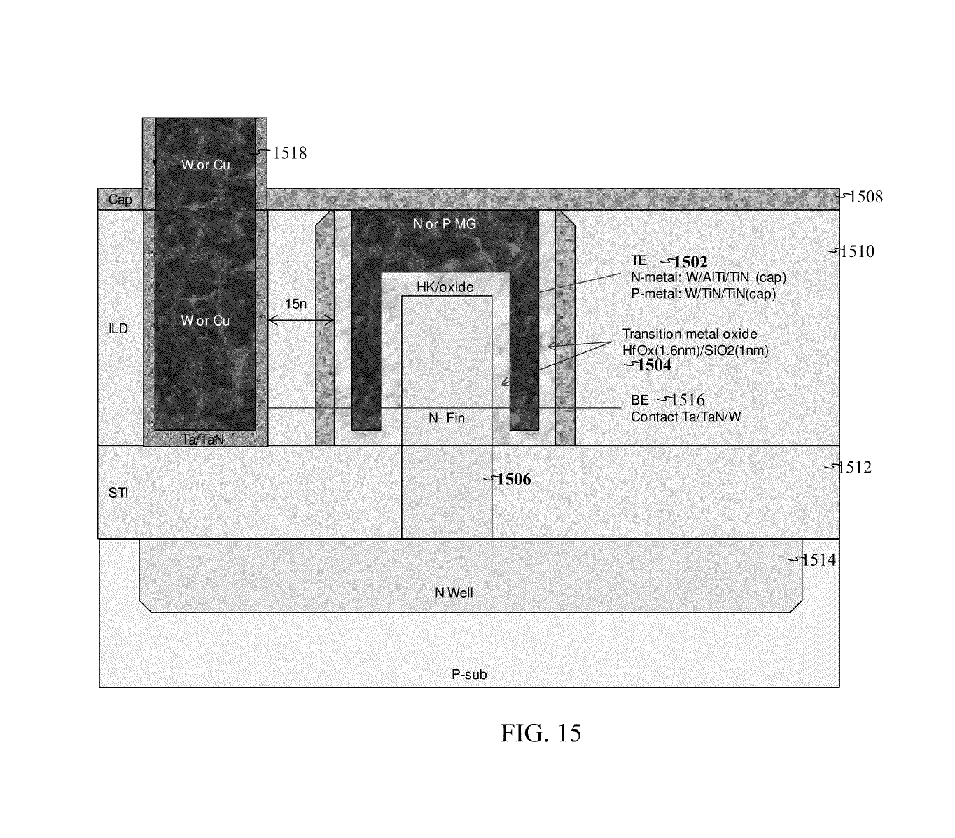

FIG. 15 illustrates an exemplary logic FinFET HK/MG RRAM MTP device 1500. The logic device 1500 can include a TE (metal gate) 1502 substantially surrounded on at least three sides by a transition metal oxide 1504. An N-Fin 1506 can be substantially surrounded on at least three sides by the TE (metal gate) 1502 and the transition metal oxide 1504. A cap layer 1508 can substantially surround the transition metal oxide 1508. The cap layer 1508 can cover an ILD 1510. The logic device can also include an STI 1512, and an N-well 1514. A contact 1516 can be embedded in the ILD 1510, substantially surrounding a BE 1516.

In some embodiments, the TE (metal gate) 1502 can include an N-metal or a P-metal. The N-metal can be various metals, such as tungsten, aluminum titanium, and titanium nitride. The P-metal can be various metals, such as tungsten and titanium nitride.

In some embodiments, the transition metal oxide 1504 can be various metals. For example, the transition metal oxide 1504 can include hafnium oxide and silicon oxide. In one example, the hafnium oxide can be 1.6 nanometers thick. In one example, the silicon oxide can be one nanometer thick.

In some embodiments, the BE 1506 can include tungsten or copper. In some embodiments, the contact 1518 can include tantalum, tantalum nitride, and tungsten. In some embodiments, there can be a distance of fifteen nanometers between the transition metal oxide 1504 and the contact 1518. In some embodiments, the cap layer 1508 can be comprised of silicon nitride.

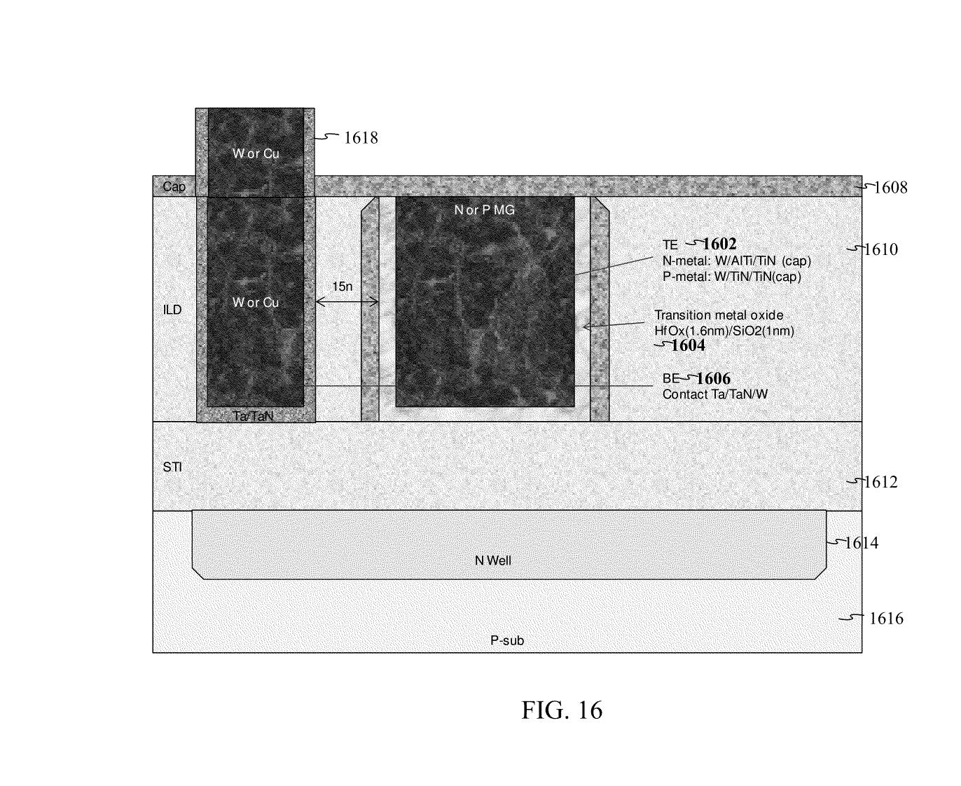

FIG. 16 illustrates an exemplary logic FinFET HK/MG RRAM MTP device 1600. The logic device 1600 can include a TE (Metal gate) 1602 substantially surrounded on at least three sides by a transition metal oxide 1604. A cap layer 1608 can substantially surround the transition metal oxide 1608. The cap layer 1608 can cover an ILD 1610. The logic device can also include an STI 1612, an N-well 1614, and a P-sub 1616. A contact 1618 can be embedded in the ILD 1610, substantially surrounding a BE 1606.

In some embodiments, the TE (metal gate) 1602 can include an N-metal or a P-metal. The N-metal can be various metals, such as tungsten, aluminum titanium, and titanium nitride. The P-metal can be various metals, such as tungsten, and titanium nitride.

In some embodiments, the transition metal oxide 1604 can be various metals. For example, the transition metal oxide 1604 can include hafnium oxide and silicon oxide. In one example, the hafnium oxide can be 1.6 nanometers thick. In one example, the silicon oxide can be one nanometer thick.

In some embodiments, the BE 1606 can include tungsten or copper. In some embodiments, the contact 1618 can include tantalum, tantalum nitride, and tungsten. In some embodiments, there can be a distance of fifteen nanometers between the transition metal oxide 1604 and the contact 1618. In some embodiments, the cap layer 1608 can be comprised of silicon nitride.

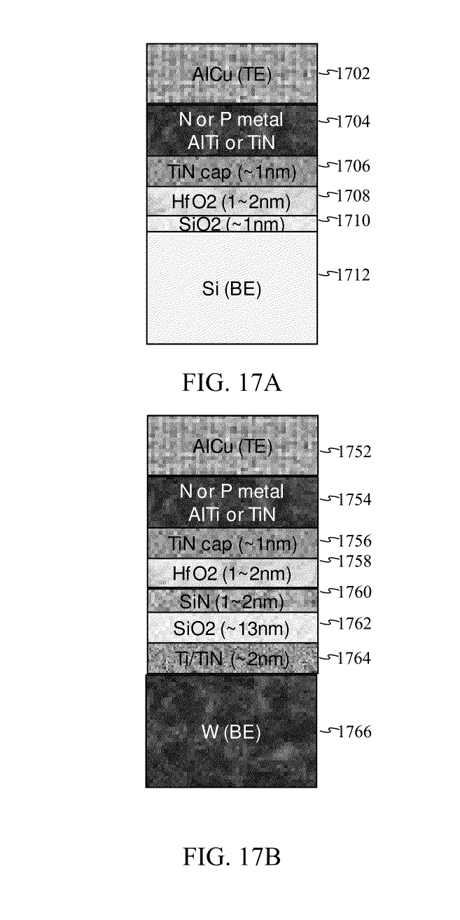

FIG. 17A illustrates exemplary materials for a logic planar HK/MG RRAM device. A top end 1702 can include aluminum copper. An N or P metal 1704 can include aluminum titanium or titanium nitride. A cap layer 1706 can include titanium nitride. The cap layer 1706 can be approximately one nanometer in thickness. The device can include a hafnium oxide layer 1708 that can be approximately one to two nanometers in thickness. The device can also include a silicon oxide layer 1710 than can be approximately one nanometer in thickness. A bottom electrode 1712 can include silicon.

FIG. 17B illustrates exemplary materials for a logic planar HK/MG RRAM device. A top end 1752 can include aluminum copper. An N or P metal 1754 can include aluminum titanium or titanium nitride. A cap layer 1756 can include titanium nitride. The cap layer 1756 can be approximately one nanometer in thickness. The device can include a hafnium oxide layer 1758 that can be approximately one to two nanometers in thickness. The device can also include a silicon nitride layer 1760 than can be approximately one to two nanometers in thickness. The device can also include a silicon oxide layer 1762 than can be approximately thirteen nanometers in thickness. The device can include a titanium and/or titanium nitride layer 1764 than can be approximately two nanometers in thickness. A bottom electrode 1766 can include tungsten.

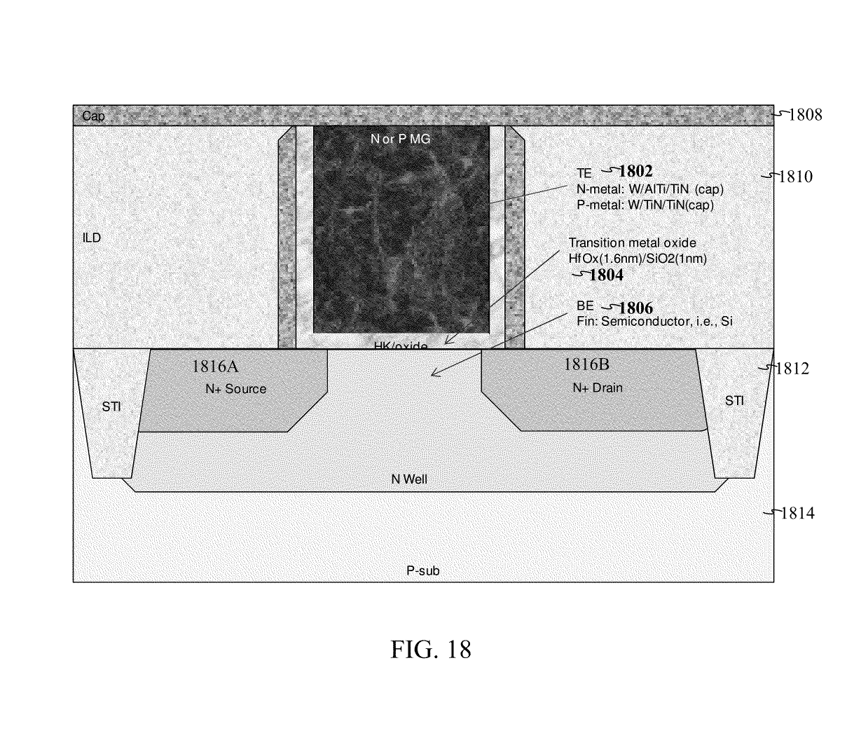

FIG. 18 illustrates an exemplary logic planar HK/MG RRAM MTP device 1800. The logic device 1800 can include a top electrode (TE) (metal gate) 1802 substantially surrounded on at least three sides by a transition metal oxide 1804. A bottom electrode (BE) (N-well) 1806 can be embedded in a P-sub 1814. A cap layer 1808 can substantially surround the transition metal oxide 1808. The cap layer 1808 can cover an interlevel dielectric layer (ILD) 1810. The logic device can also include a shallow trench isolation (STI) 1812, an N+ Source 1816A, and an N+ Drain 1816B.

In some embodiments, the TE (metal gate) 1802 can include an N-metal or a P-metal. The N-metal can be various metals, such as tungsten, aluminum titanium, and titanium nitride. The P-metal can be various metals, such as tungsten, and titanium nitride.

In some embodiments, the transition metal oxide 1804 can be various metals. For example, the transition metal oxide 1804 can include hafnium oxide and silicon oxide. In one example, the hafnium oxide can be 1.6 nanometers thick. In one example, the silicon oxide can be one nanometer thick.

In some embodiments, the BE 1806 can include an N-well including a semiconductor channel. The BE can include a semiconductor, such as silicon. In some embodiments, the cap layer 1808 can be comprised of silicon nitride.

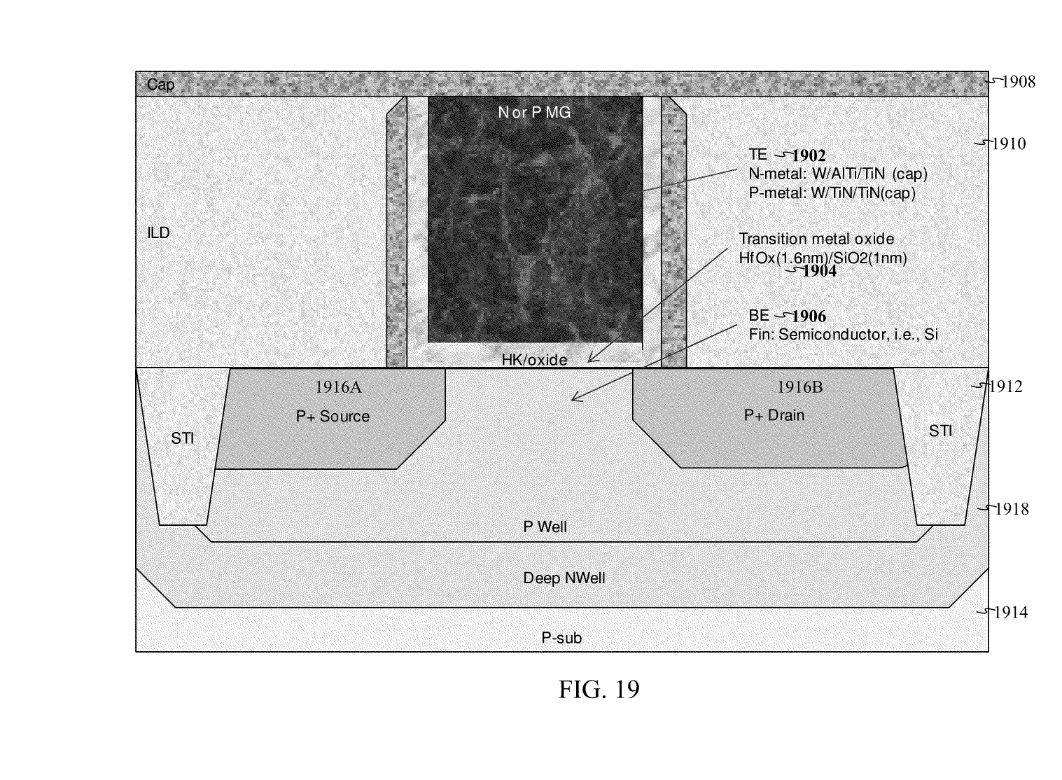

FIG. 19 illustrates an exemplary logic planar HK/MG RRAM MTP device 1900. The logic device 1900 can include a top electrode (TE) (metal gate) 1902 substantially surrounded on at least three sides by a transition metal oxide 1904. A bottom electrode (BE) (P-well) 1906 can be embedded in a deep N-well 1918. A cap layer 1908 can substantially surround the transition metal oxide 1908. The cap layer 1908 can cover an interlevel dielectric layer (ILD) 1910. The logic device can also include a shallow trench isolation (STI) 1912, a P-sub 1914, a P+ Source 1916A, and a P+ Drain 1916B.

In some embodiments, the TE (metal gate) 1902 can include an N-metal or a P-metal. The N-metal can be various metals, such as tungsten, aluminum titanium, and titanium nitride. The P-metal can be various metals, such as tungsten, and titanium nitride.

In some embodiments, the transition metal oxide 1904 can be various metals. For example, the transition metal oxide 1904 can include hafnium oxide and silicon oxide. In one example, the hafnium oxide can be 1.6 nanometers thick. In one example, the silicon oxide can be one nanometer thick.

In some embodiments, the BE (P-well) 1906 can include a P-well including a semiconductor channel. The BE can include a semiconductor, such as silicon. In some embodiments, the cap layer 1908 can be comprised of silicon nitride.

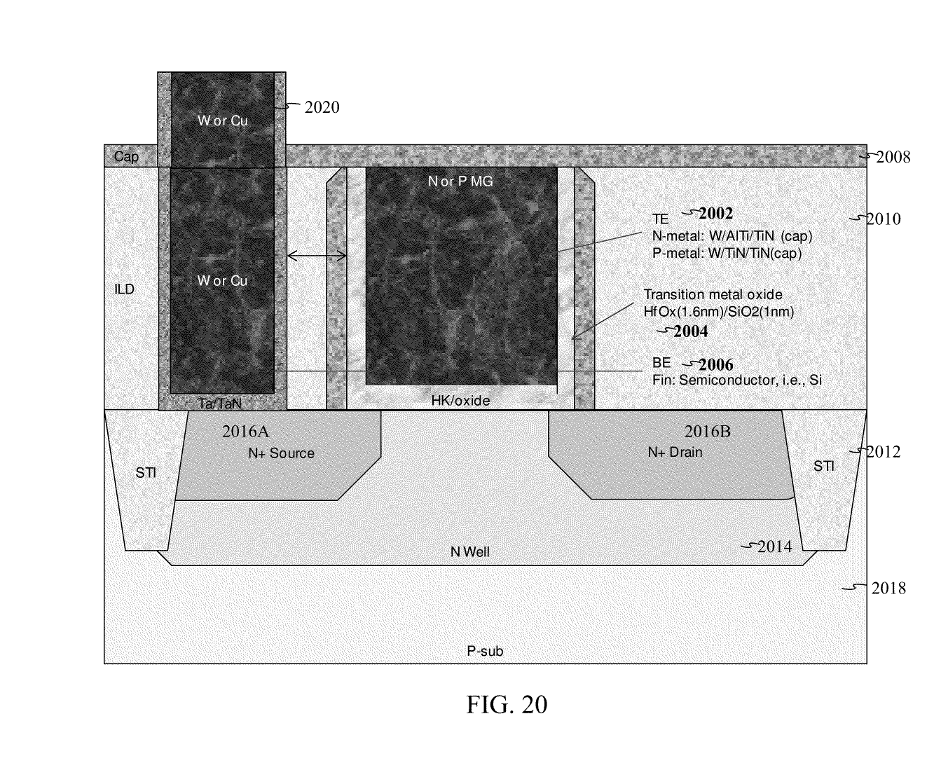

FIG. 20 illustrates an exemplary logic planar HK/MG RRAM MTP device 2000. The logic device 2000 can include a TE (metal gate) 2002 substantially surrounded on at least three sides by a transition metal oxide 2004. A cap layer 2008 can substantially surround the transition metal oxide 2008. The cap layer 2008 can cover an ILD 2010. The logic device can also include an STI 2012, an N-well 2014, an N+ Source 2016A, an N+ Drain 2016B, and a P-sub 2018. A contact 2020 can be embedded in the ILD 2010, substantially surrounding a BE 2006.

In some embodiments, the TE (metal gate) 2002 can include an N-metal or a P-metal. The N-metal can be various metals, such as tungsten, aluminum titanium, and titanium nitride. The P-metal can be various metals, such as tungsten, and titanium nitride.

In some embodiments, the transition metal oxide 2004 can be various metals. For example, the transition metal oxide 2004 can include hafnium oxide and silicon oxide. In one example, the hafnium oxide can be 1.6 nanometers thick. In one example, the silicon oxide can be one nanometer thick.

In some embodiments, the BE (Contact) 2006 can include tungsten or copper. In some embodiments, the contact 2020 can include tantalum, tantalum nitride, and tungsten. In some embodiments, there can be a distance of fifteen nanometers between the transition metal oxide 2004 and the contact 2018. In some embodiments, the cap layer 2008 can be comprised of silicon nitride.

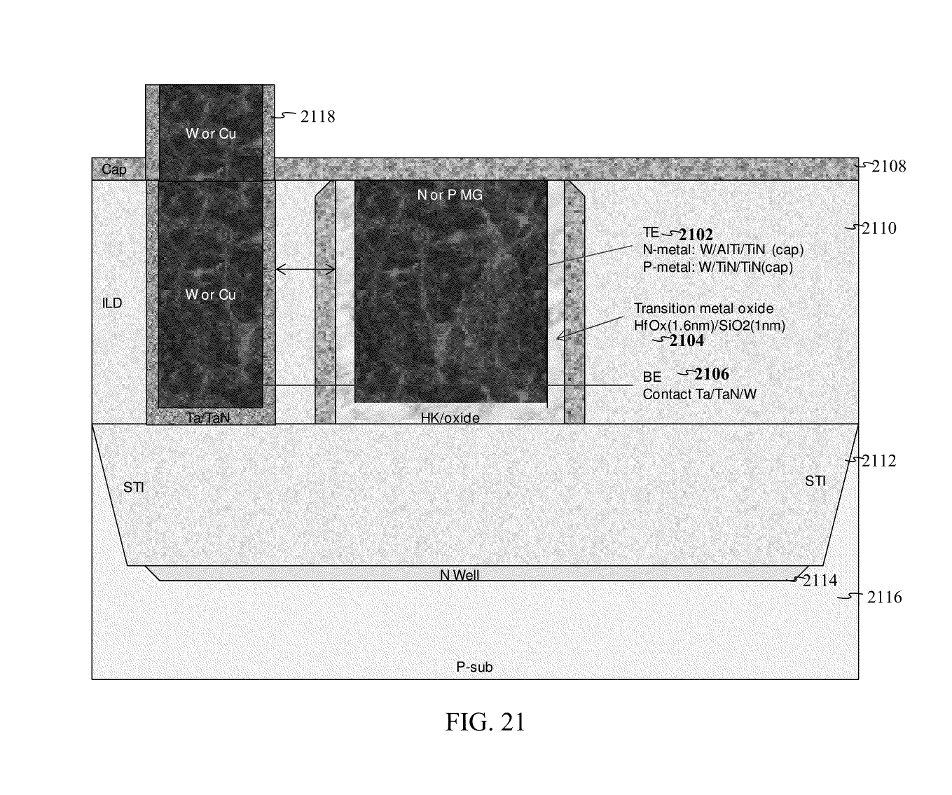

FIG. 21 illustrates an exemplary logic planar HK/MG RRAM MTP device 2100. The logic device 2100 can include a TE (metal gate) 2102 substantially surrounded on at least three sides by a transition metal oxide 2104. A cap layer 2108 can substantially surround the transition metal oxide 2108. The cap layer 2108 can cover an ILD 2110. The logic device can also include an STI 2112, an N-well 2114, and a P-sub 2116. A contact 2118 can be embedded in the ILD 2110, substantially surrounding a BE 2106.

In some embodiments, the TE (metal gate) 2102 can include an N-metal or a P-metal. The N-metal can be various metals, such as tungsten, aluminum titanium, and titanium nitride. The P-metal can be various metals, such as tungsten, and titanium nitride.

In some embodiments, the transition metal oxide 2104 can be various metals. For example, the transition metal oxide 2104 can include hafnium oxide and silicon oxide. In one example, the hafnium oxide can be 1.6 nanometers thick. In one example, the silicon oxide can be one nanometer thick.

In some embodiments, the BE 2106 can include tungsten or copper. In some embodiments, the contact 2118 can include tantalum, tantalum nitride, and tungsten. In some embodiments, there can be a distance of fifteen nanometers between the transition metal oxide 2104 and the contact 2118. In some embodiments, the cap layer 2108 can be comprised of silicon nitride.

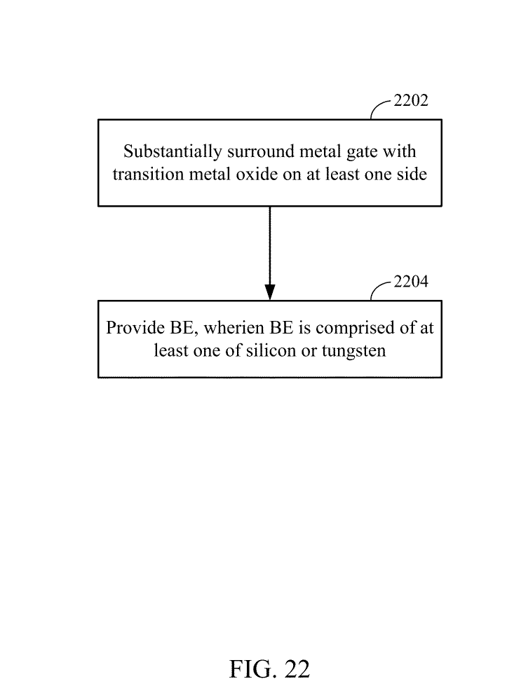

FIG. 22 illustrates an embodiment that can include a method comprising: substantially surrounding a metal gate with a transition metal oxide on at least one side, wherein the transition metal oxide is comprised of hafnium oxalate and silicon dioxide—Block 2202; and providing a bottom electrode (BE), wherein the BE is comprised of at least one of silicon or tungsten—Block 2204.

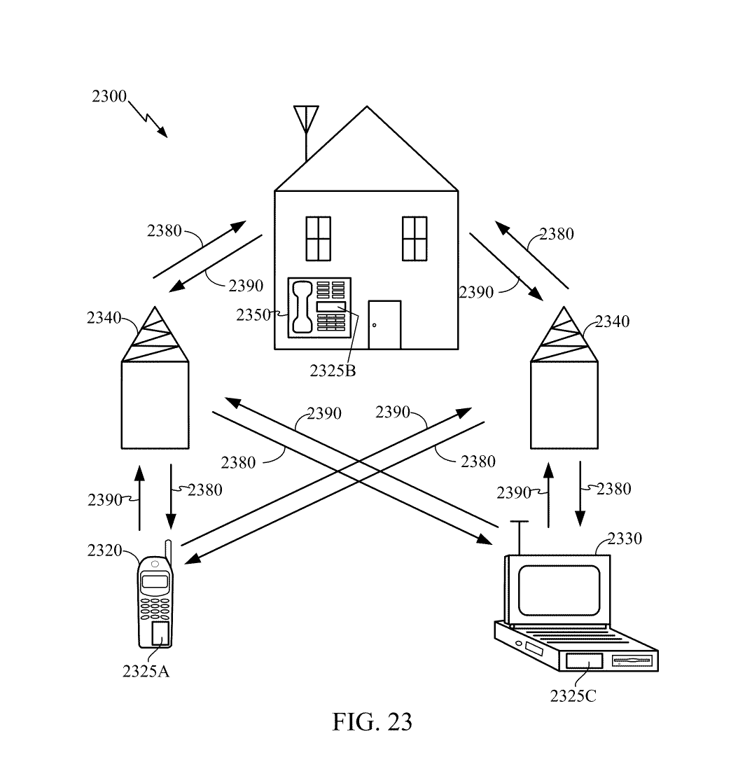

FIG. 23 is a block diagram showing an exemplary wireless communication system 2300 in which an embodiment of the disclosure may be advantageously employed. For purposes of illustration, FIG. 23 shows three remote units 2320, 2330, and 2350 and two base stations 2340. It will be recognized that wireless communication systems may have many more remote units and base stations. Remote units 2320, 2330, and 2350 include IC devices 2325A, 2325B and 2325C, as disclosed below. It will be recognized that any device containing an IC may also include a coupled inductor having the disclosed features and/or components manufactured by the processes disclosed here, including the base stations, switching devices, and network equipment. FIG. 23 shows forward link signals 2380 from the base station 2340 to the remote units 2320, 2330, and 2350 and reverse link signals 2390 from the remote units 2320, 2330, and 2350 to base stations 2340.

In FIG. 23, the remote unit 2320 is shown as a mobile telephone, the remote unit 2330 is shown as a portable computer, and the remote unit 2350 is shown as a fixed location remote unit in a wireless local loop system. For example, the remote units may be a device such as a music player, a video player, an entertainment unit, a navigation device, a communications device, a personal digital assistant (PDA), a fixed location data unit, and a computer. Although FIG. 23 illustrates remote units according to the teachings of the disclosure, the disclosure is not limited to these exemplary illustrated units. The disclosure may be suitably employed in any device which includes a logic device, as described above.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an electronic object. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, DSL, or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes CD, laser disc, optical disc, DVD, floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

1. An apparatus comprising:
a metal gate, wherein a transition metal oxide substantially surrounds the metal gate on at least one side;
the transition metal oxide, wherein the transition metal oxide is comprised of hafnium oxide and silicon dioxide;
a bottom electrode (BE), wherein the BE is comprised of at least one of silicon or tungsten;
a contact surrounding the BE, the contact comprising a material selected from the group consisting of tantalum, tantalum nitride, and tungsten; and
an interlevel dielectric layer (ILD) surrounding the contact.

2. The apparatus of claim 1, further comprising a cap layer over at least one of the metal gate or the transition metal oxide.

3. The apparatus of claim 1, wherein the apparatus is a logic gated diode for Resistive Random Access Memory (RRAM).

4. The apparatus of claim 3, wherein the logic gated diode comprises an N-well and an N-Fin.

5. The apparatus of claim 3, wherein the logic gated diode comprises a P-well and a P-Fin.

6. The apparatus of claim 3, wherein the logic gated diode comprises an N-well, an N+ Source and an N+ Drain.

7. The apparatus of claim 3, wherein the logic gated diode comprises a P-Well, a P-Source, and a P-Drain.

8. The apparatus of claim 1, wherein the apparatus is a logic gate to a metal-insulator-metal capacitor RRAM device.

9. The apparatus of claim 8, wherein the logic gate comprises an N-well and an N-Fin.

10. The apparatus of claim 8, wherein the logic gate comprises a P-well and a P-Fin.

11. The apparatus of claim 8, wherein the logic gate comprises an N-well, an N+ Source and an N+ Drain.

12. The apparatus of claim 8, wherein the logic gate comprises a shallow trench isolator (STI), wherein the STI isolates an N-well.

13. A method for providing a logic device, comprising:
substantially surrounding a metal gate with a transition metal oxide on at least one side, wherein the transition metal oxide is comprised of hafnium oxide and silicon dioxide;
providing a bottom electrode (BE), wherein the BE is comprised of at least one of silicon or tungsten;
providing a contact surrounding the BE, the contact comprising a material selected from the group consisting of tantalum, tantalum nitride, and tungsten; and
providing an interlevel dielectric layer (ILD) surrounding the contact.

14. The method of claim 13, further comprising providing a cap layer over at least one of the metal gate or the transition metal oxide.

15. The method of claim 13, further comprising providing a diode Resistive Random Access Memory (RRAM) multi-time programmable (MTP)/one-time programmable (OTP) device.

16. The method of claim 15, further comprising making a hard breakdown of the metal gate to realize an OTP state.

17. The method of claim 15, further comprising performing a bidirectional write operation to set and reset an MTP state.

18. The method of claim 13, further comprising contacting a metal-insulator-metal capacitor RRAM device.

19. The method of claim 13, further comprising coupling the logic device with a front-end-of-the-line/middle-end-of-the-line device.

20. An embedded non-volatile memory device comprising:
a metal gate, wherein a transition metal oxide substantially surrounds the metal gate on at least one side;
the transition metal oxide, wherein the transition metal oxide is comprised of hafnium oxide and silicon dioxide;
a bottom electrode (BE), wherein the BE is comprised of at least one of silicon or tungsten;
a contact surrounding the BE, the contact comprising a material selected from the group consisting of tantalum, tantalum nitride, and tungsten; and
an interlevel dielectric layer (ILD) surrounding the contact.
